(19) United States
(12) Patent Application Publication
(10) Pub. No.: US 2023/0200144 A1
(43) Pub. Date: Jun. 22, 2023

(54) DISPLAY PANEL, DISPLAY APPARATUS, AND FABRICATION METHOD

(71) Applicant: BOE TECHNOLOGY GROUP CO., LTD., BEIJING (CN)

(72) Inventors: Guoying WANG, BEIJING (CN); Pan XU, BEIJING (CN); Xing ZHANG, BEIJING (CN); Ying HAN, BEIJING (CN); Zhan GAO, BEIJING (CN); Zhen SONG, BEIJING (CN)

(73) Assignee: BOE TECHNOLOGY GROUP CO., LTD., BEIJING (CN)

(21) Appl. No.: 17/999,002

(22) PCT Filed: Oct. 22, 2021
(86) PCT No.: PCT/CN2021/125635

§ 371 Date: Nov. 16, 2022

(30) Foreign Application Priority Data
Jan. 26, 2021 (CN) 202110105603.8

(51) Int. Cl. H10K 59/122; H10K 59/121; H10K 59/12

(52) U.S. Cl. CPC H10K 59/122; H10K 59/1216; H10K 59/1201

(57) ABSTRACT

The present disclosure provides a display panel, a display apparatus, and a fabrication method. The display panel includes: a substrate; a first insulating layer on the substrate; a device structure layer on the first insulating layer and including a transparent capacitor and a transistor; a first planarization layer that covers the device structure layer; a first electrode layer on the first planarization layer; a pixel defining layer on the side of the first planarization layer and device structure layer away from the substrate, wherein an orthographic projection of an opening of the pixel defining layer on the substrate at least partially overlaps with an orthographic projection of the transparent capacitor on the substrate; a functional layer at least partially located in the opening; and a second electrode layer on the side of the functional layer away from the first electrode layer.

### CROSS-REFERENCE TO RELATED APPLICATIONS

The present application is a U.S. National Stage Application under 35 U.S.C. § 371 of International Patent Application No. PCT/CN2021/125635, filed on Oct. 22, 2021, which claims priority to China Patent Application No. 202110105603.8 filed on Jan. 26, 2021, the disclosure of both of which are incorporated by reference herein in entirety.

### TECHNICAL FIELD

The present disclosure relates to a display panel, a display device and a manufacturing method.

### BACKGROUND

At present, large size and ultra-high definition have become two development directions of the display technology. From 720P to 1080P, and from 2K to 4K to 8K, the upgrade of the display resolution has always been a dominant trend in the development of the display industry. The opening rate of the pixel is a main factor to improve the resolution of the display panel. In the design of each sub-pixel in the related art, a TFT (Thin Film Transistor) and a capacitor are usually connected together, and each sub-pixel has its own pixel capacitance structure.

### SUMMARY

According to an aspect of embodiments of the present disclosure, a display panel is provided. The display panel comprises: a substrate; a first insulating layer on the substrate; a device structure layer on a side of the first insulating layer away from the substrate, wherein the device structure layer comprises a transparent capacitor and a transistor electrically connected to the transparent capacitor; a first planarization layer covering at least a portion of the device structure layer; a first electrode layer on a side of the first planarization layer away from the substrate, wherein the first electrode layer is electrically connected to the transparent capacitor, and the first electrode layer is a transparent electrode layer; a pixel defining layer on a side of the first planarization layer and the device structure layer away from the substrate, the pixel defining layer having an opening exposing at least a portion of the first electrode layer, wherein an orthographic projection of the opening on the substrate at least partially overlaps with an orthographic projection of the transparent capacitor on the substrate; a functional layer at least partially located in the opening, wherein the functional layer is in contact with the first electrode layer, and the functional layer comprises a light-emitting layer; and a second electrode layer on a side of the functional layer away from the first electrode layer.

In some embodiments, the display panel further comprises a color filter layer between the substrate and the first insulating layer.

In some embodiments, an orthographic projection of the color filter layer on the substrate at least partially overlaps with the orthographic projection of the opening on the substrate.

In some embodiments, the orthographic projection of the opening on the substrate is inside the orthographic projection of the transparent capacitor on the substrate.

In some embodiments, the transparent capacitor comprises a third electrode layer on a side of the first insulating layer away from the substrate, a second insulating layer on the first insulating layer and covering the third electrode layer, and a fourth electrode layer on a side of the second insulating layer away from the third electrode layer, wherein the third electrode layer and the fourth electrode layer are transparent electrode layers, an area of the fourth electrode layer is less than an area of the third electrode layer, and the orthographic projection of the opening on the substrate is inside an orthographic projection of the fourth electrode layer on the substrate.

In some embodiments, the color filter layer comprises a first color filter portion and a second color filter portion located in a same layer as the first color filter portion and spaced apart from the first color filter portion, wherein the orthographic projection of the opening on the substrate is inside an orthographic projection of the first color filter portion on the substrate, and the orthographic projection of the first color filter portion on the substrate is inside the orthographic projection of the fourth electrode layer on the substrate.

In some embodiments, the transistor comprises: an active layer on a side of the second insulating layer away from the substrate; a gate insulating layer on a side of the active layer away from the second insulating layer; a gate electrode on a side of the gate insulating layer away from the active layer, wherein the gate electrode is electrically connected to the fourth electrode layer through a first connecting member; and a fifth electrode layer electrically connected to the active layer, wherein the fifth electrode layer is electrically connected to the third electrode layer.

In some embodiments, the device structure layer further comprises: an interlayer insulating layer covering the fourth electrode layer, the second insulating layer, the active layer and the gate electrode.

In some embodiments, the first connecting member is connected to the fourth electrode layer through a first through hole passing through the interlayer insulating layer and exposing a part of the fourth electrode layer, and the first connecting member is connected to the gate electrode through a second through hole passing through the interlayer insulating layer and exposing a part of the gate electrode; the fifth electrode layer is connected to the active layer through a third through hole passing through the interlayer insulating layer and exposing a part of the active layer, and the fifth electrode layer is connected to the third electrode layer through a fourth through hole passing through the interlayer insulating layer and the second insulating layer and exposing a part of the third electrode layer; and the first electrode layer is electrically connected to the third electrode layer through a second connecting member, wherein the second connecting member is connected to the third electrode layer through a fifth through hole passing through the first planarization layer, the interlayer insulating layer and the second insulating layer and exposing another part of the third electrode layer.

In some embodiments, an orthographic projection of the active layer on the substrate is inside an orthographic projection of the second color filter portion on the substrate.

In some embodiments, the first connecting member, the fifth electrode layer and the second connecting member each comprise: a transparent conductive layer and a metal layer on a side of the transparent conductive layer away from the substrate.

In some embodiments, the display panel further comprises a passivation layer between the pixel defining layer and the device structure layer.

In some embodiments, the first insulating layer comprises: a second planarization layer on the substrate; and a buffer layer on a side of the second planarization layer away from the substrate.

According to another aspect of the embodiments of the present disclosure, a display device is provided. The display device comprises the display panel described above.

According to an aspect of the embodiments of the present disclosure, a manufacturing method of a display panel is provided. The manufacturing method comprises: forming a first insulating layer on a substrate; forming a device structure layer on a side of the first insulating layer away from the substrate, wherein the device structure layer comprises a transparent capacitor and a transistor electrically connected to the transparent capacitor; forming a first planarization layer covering at least a portion of the device structure layer; forming a first electrode layer on a side of the first planarization layer away from the substrate, wherein the first electrode layer is electrically connected to the transparent capacitor, and the first electrode layer is a transparent electrode layer; forming a pixel defining layer on a side of the first planarization layer and the device structure layer away from the substrate, the pixel defining layer having an opening exposing at least a portion of the first electrode layer, wherein an orthographic projection of the opening on the substrate at least partially overlaps with an orthographic projection of the transparent capacitor on the substrate; forming a functional layer at least partially located in the opening, wherein the functional layer is in contact with the first electrode layer, and the functional layer comprises a light-emitting layer; and forming a second electrode layer on a side of the functional layer away from the first electrode layer.

In some embodiments, the manufacturing method further comprises: forming a patterned color filter layer on the substrate before forming the first insulating layer, wherein the color filter layer is covered by the first insulating layer.

In some embodiments, the forming of the device structure layer comprises: forming the transparent capacitor and the transistor; wherein the forming of the transparent capacitor comprises: forming a third electrode layer on a side of the first insulating layer away from the substrate; forming a second insulating layer on the first insulating layer, the second insulating layer covering the third electrode layer; and forming a fourth electrode layer on a side of the second insulating layer away from the third electrode layer; wherein the third electrode layer and the fourth electrode layer are transparent electrode layers, an area of the fourth electrode layer is less than an area of the third electrode layer, and the orthographic projection of the opening on the substrate is inside an orthographic projection of the fourth electrode layer on the substrate.

In some embodiments, the forming of the transistor comprises: forming an active layer on a side of the second insulating layer away from the substrate, wherein the active layer and the fourth electrode layer are formed by a same patterning process; forming a gate insulating layer on a side of the active layer away from the second insulating layer; forming a gate electrode on a side of the gate insulating layer away from the active layer, wherein the gate electrode is electrically connected to the fourth electrode layer through a first connecting member; and forming a fifth electrode layer electrically connected to the active layer, wherein the fifth electrode layer is electrically connected to the third electrode layer.

In some embodiments, the forming of the device structure layer further comprises: forming an interlayer insulating layer covering the fourth electrode layer, the second insulating layer, the active layer and the gate electrode; and the manufacturing method further comprises: forming a first through hole, a second through hole, a third through hole, a fourth through hole and a first portion of a fifth through hole by a same etching process, the first through hole passing through the interlayer insulating layer and exposing a part of the fourth electrode layer, the second through hole passing through the interlayer insulating layer and exposing a part of the gate electrode, the third through hole passing through the interlayer insulating layer and exposing a part of the active layer, the fourth through hole passing through the interlayer insulating layer and the second insulating layer and exposing a part of the third electrode layer, and the first portion of the fifth through hole passing through the interlayer insulating layer and the second insulating layer and exposing another part of the third electrode layer; and etching the first planarization layer to form a second portion of the fifth through hole passing through the first planarization layer after forming the first planarization layer, wherein the second portion is aligned with the first portion; wherein the first connecting member, the fifth electrode layer, the first electrode layer and a second connecting member are formed by deposition and patterning processes after forming the first through hole, the second through hole, the third through hole, the fourth through hole and the fifth through hole, wherein the second connecting member is connected to the first electrode layer and the third electrode layer.

In some embodiments, the manufacturing method further comprises: forming a passivation layer covering the first planarization layer and the device structure layer before forming the pixel defining layer; and forming the opening passing through the pixel defining layer and the passivation layer by a patterning process after forming the pixel defining layer covering the passivation layer.

Other features and advantages of the present disclosure will become apparent from the following detailed description of exemplary embodiments of the present disclosure in conjunction with the accompanying drawings.

### BRIEF DESCRIPTION OF THE ACCOMPANYING DRAWINGS

The accompanying drawings which constitute part of this specification, illustrate the exemplary embodiments of the present disclosure, and together with this specification, serve to explain the principles of the present disclosure.

The present disclosure may be more explicitly understood from the following detailed description with reference to the accompanying drawings, in which:

FIG. 1 is a schematic cross-sectional view showing a display panel according to an embodiment of the present disclosure;

FIG. 2 is a schematic cross-sectional view showing a display panel according to another embodiment of the present disclosure;

FIG. 3 is a flow chart showing a manufacturing method of a display panel according to an embodiment of the present disclosure;

FIG. 4 is a schematic cross-sectional view showing a structure in a stage during a manufacturing process of a display panel according to an embodiment of the present disclosure;

FIG. 5 is a schematic cross-sectional view showing a structure in another stage during a manufacturing process of a display panel according to an embodiment of the present disclosure;

FIG. 6 is a schematic cross-sectional view showing a structure in another stage during a manufacturing process of a display panel according to an embodiment of the present disclosure;

FIG. 7 is a schematic cross-sectional view showing a structure in another stage during a manufacturing process of a display panel according to an embodiment of the present disclosure;

FIG. 8 is a schematic cross-sectional view showing a structure in another stage during a manufacturing process of a display panel according to an embodiment of the present disclosure.

It should be understood that the dimensions of the various parts shown in the accompanying drawings are not drawn according to the actual scale. In addition, the same or similar reference signs are used to denote the same or similar components.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The inventors of the present disclosure have found that, in each sub-pixel in the related art, TFT is connected to the pixel capacitor, and besides TFT, the pixel capacitor also occupies a relatively large area, which results in sacrificing a certain opening rate of the sub-pixel. When such sub-pixels are applied to a display with a high PPI (Pixels Per Inch, the number of pixels per inch, that is, pixel density), as restricted by the line width and the design rules, the opening rate may be further reduced, which leads to problems such as increased power consumption of the display and attenuated service life of the light-emitting layer.

In view of this, an embodiment of the present disclosure provides a display panel to improve the opening rate of sub-pixels of the display panel. The display panel according to some embodiments of the present disclosure will be described in detail below in conjunction with the accompanying drawings.

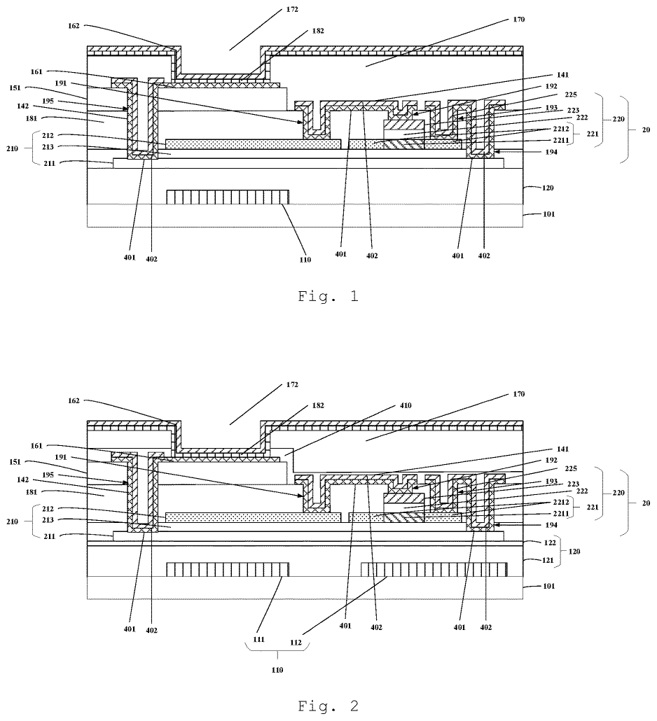

FIG. 1 is a schematic cross-sectional view showing a display panel according to an embodiment of the present disclosure.

As shown in FIG. 1, the display panel comprises a substrate 101. For example, the substrate 101 is a glass substrate. The display panel further comprises a first insulating layer 120 on the substrate 101.

As shown in FIG. 1, the display panel further comprises a device structure layer 20 on a side of the first insulating layer 120 away from the substrate 101. The device structure layer 20 comprises a transparent capacitor 210 and a transistor 220 electrically connected to the transparent capacitor 210. Here, the transparent capacitor refers to a capacitor using a transparent electrode layer as an electrode layer.

In some embodiments, as shown in FIG. 1, the transparent capacitor 210 comprises a third electrode layer 211 on a side of the first insulating layer 120 away from the substrate 101, a second insulating layer 213 on the first insulating layer 120 and covering the third electrode layer 211, and a fourth electrode layer 212 on a side of the second insulating layer 213 away from the third electrode layer 211. The third electrode layer 211 and the fourth electrode layer 212 are transparent electrode layers. For example, an area of the fourth electrode layer 212 is less than an area of the third electrode layer 213. This facilitates the connection of another structure with the third electrode layer 211.

In some embodiments, a material of the third electrode layer 211 comprises a TCO (Transparent Conductive Oxide) material. For example, the TCO material may comprise a transparent oxide semiconductor material such as ITO (Indium Tin Oxide), AZO (Aluminium Zinc Oxide), or IZO (Indium Zinc Oxide). For another example, the TCO material may comprise thin metallic materials such as Mg/Ag (magnesium/silver), Ca/Ag (calcium/silver), Sm/Ag (samarium/silver), Al/Ag (aluminum/silver), Ba/Ag (barium/silver) or other composite materials. In some embodiments, the third electrode layer 211 comprises a TCO layer and a metal layer on the TCO layer. For example, a material of the metal layer may comprise at least one of Mo (molybdenum), Al (aluminum), Ti (titanium), Au (gold), Cu (copper), Hf (hafnium), Ta (tantalum), or the like, or may comprise alloys such as AlNd (aluminum neodymium) or MoNb (molybdenum niobium).

In some embodiments, a material of the fourth electrode layer 212 comprises a TCO material. For example, the material of the fourth electrode layer 212 comprises a metal oxide material. For example, the metal oxide material comprises an IGZO (indium gallium zinc oxide) material.

In some embodiments, a material of the second insulating layer 213 comprises silicon oxide, silicon nitride, silicon oxynitride, or the like.

In some embodiments, as shown in FIG. 1, the transistor 220 comprises an active layer 221 on a side of the second insulating layer 213 away from the substrate 101. The active layer 221 may comprise a channel area 2211 and an LDD (Lightly Doped Drain) area 2212 on both sides of the channel area 2211. For example, a material of the active layer 221 comprises a metal oxide material, such as an IGZO material. For another example, the material of the active layer 221 comprises: a-IGZO (amorphous indium gallium zinc oxide), ZnON (zinc oxynitride), IZTO (indium zinc tin oxide), a-Si (amorphous silicon), p-Si (polysilicon), hexathiophene polythiophene, or the like.

In some embodiments, a material of the active layer 221 is the same as the material of the fourth electrode layer 212. In this way, it is convenient to form the active layer and the fourth electrode layer by the same patterning process and reduce the photoetching times.

As shown in FIG. 1, the transistor 220 further comprises a gate insulating layer 222 on a side of the active layer 221 away from the second insulating layer 213. For example, a material of the gate insulating layer 222 comprises an insulating material such as silicon oxide, silicon nitride or silicon oxynitride.

As shown in FIG. 1, the transistor 220 further comprises a gate electrode 223 on a side of the gate insulating layer 222 away from the active layer 221. A material of the gate electrode 223 comprises a metal material. For example, the material of the gate electrode 223 comprises at least one of Mo, Al, Ti, Au, Cu, Hf, Ta, or the like. For another example, the gate electrode 223 may comprise a three-layer structure of MoNd (molybdenum neodymium alloy)/Cu/MoNd.

As shown in FIG. 1, the gate electrode 223 is electrically connected to the fourth electrode layer 212 through a first connecting member 141. The first connecting member 141 is connected to the fourth electrode layer 212 through a first through hole 191, wherein the first through hole 191 passes through an interlayer insulating layer 181 (to be described later) and exposes a part of the fourth electrode layer 212. The first connecting member 141 is connected to the gate electrode 223 through a second through hole 192, wherein the second through hole 192 passes through the interlayer insulating layer 181 and exposes a part of the gate electrode 223. The first connecting member 141 comprises: a transparent conductive layer 401 and a metal layer 402 on a side of the transparent conductive layer 401 away from the substrate 101. The transparent conductive layer 401 is closer to the substrate 101 than the metal layer 402. The transparent conductive layer 401 is on the interlayer insulating layer 181. For example, the transparent conductive layer 401 comprises an ITO layer, and the metal layer 402 comprises at least one of Mo, Al, Ti, Au, Cu, Hf, Ta, or the like. Here, the first connecting member adopts a double-layer structure, which can reduce the resistance. Of course, those skilled in the art can understand that the first connecting member may also adopt a single-layer structure. For example, the first connecting member may be a single-layer transparent conductive layer or a single-layer metal layer. Therefore, the scope of the embodiments of the present disclosure is not limited thereto.

As shown in FIG. 1, the transistor 220 further comprises a fifth electrode layer 225 electrically connected to the active layer 221. For example, the fifth electrode layer 225 comprises a transparent conductive layer 401 and a metal layer 402 on a side of the transparent conductive layer 401 away from the substrate 101. Here, the fifth electrode layer adopts a double-layer structure, which can reduce the resistance. Of course, those skilled in the art can understand that the fifth electrode layer may also adopt a single-layer structure. For example, the fifth conductive layer may be a single-layer transparent conductive layer or a single-layer metal layer. Therefore, the scope of the embodiments of the present disclosure is not limited thereto.

As shown in FIG. 1, the fifth electrode layer 225 is electrically connected to the third electrode layer 211. The fifth electrode layer 225 is connected to the active layer 221 through a third through hole 193, wherein the third through hole 193 passes through the interlayer insulating layer 181 and exposes a part of the active layer 221. The fifth electrode layer 225 is connected to the third electrode layer 211 through a fourth through hole 194, wherein the fourth through hole 211 passes through the interlayer insulating layer 181 and the second insulating layer 213 and exposes a part of the third electrode layer 211.

In some embodiments, the device structure layer 20 further comprises: the interlayer insulating layer 181 covering the fourth electrode layer 212, the second insulating layer 213, the active layer 221 and the gate electrode 223. For example, a material of the interlayer insulating layer 181 comprises silicon oxide, silicon nitride, or the like.

As shown in FIG. 1, the display panel further comprises a first planarization layer 151 covering at least a portion of the device structure layer 20. For example, a material of the first planarization layer 151 comprises a planarization material such as resin, SOG (spin on glass coating) or BCB (benzocyclobutene).

As shown in FIG. 1, the display panel further comprises a first electrode layer 161 on a side of the first planarization layer 151 away from the substrate 101. For example, the first electrode layer 161 is an anode layer. The first electrode layer 161 is a transparent electrode layer. For example, a material of the first electrode layer 161 comprises TCO (for example, ITO).

The first electrode layer 161 is electrically connected to the transparent capacitor 210. For example, as shown in FIG. 1, the first electrode layer 161 is electrically connected to the third electrode layer 211 through a second connecting member 142. The second connecting member 142 is connected to the third electrode layer 211 through a fifth through hole 195, wherein the fifth through hole 195 passes through the first planarization layer 151, the interlayer insulating layer 181 and the second insulating layer 213 and exposes another part of the third electrode layer 211. For example, the second connecting member 142 comprises a transparent conductive layer 401 and a metal layer 402 on a side of the transparent conductive layer 401 away from the substrate 101. Here, the second connecting member adopts a double-layer structure, which can reduce the resistance. Of course, those skilled in the art can understand that the second connecting member may also adopt a single-layer structure. For example, the second connecting member may be a single-layer transparent conductive layer or a single-layer metal layer. Therefore, the scope of the embodiments of the present disclosure is not limited thereto.

As shown in FIG. 1, the display panel further comprises a pixel defining layer 170 on a side of the first planarization layer 151 and the device structure layer 20 away from the substrate 101. The pixel defining layer 170 has an opening 172 exposing at least a portion of the first electrode layer 161. An orthographic projection of the opening 172 on the substrate 101 at least partially overlaps with an orthographic projection of the transparent capacitor 210 on the substrate 101. In some embodiments, the orthographic projection of the opening 172 on the substrate 101 is inside the orthographic projection of the transparent capacitor 210 on the substrate 101. For example, the orthographic projection of the opening 172 on the substrate 101 is inside an orthographic projection of the fourth electrode layer 212 on the substrate 101. This makes the opening to be located directly above the transparent capacitor, so that the opening rate of the sub-pixel can be improved.

As shown in FIG. 1, the display panel further comprises a functional layer 182 at least partially located in the opening 172. The functional layer 182 is in contact with the first electrode layer 161. The functional layer 182 comprises a light-emitting layer.

As shown in FIG. 1, the display panel further comprises a second electrode layer 162 on a side of the functional layer 182 away from the first electrode layer 161. For example, the second electrode layer 162 is a reflective cathode layer. For example, a material of the second electrode layer 162 comprises a metal material such as Al or an alloy thereof.

So far, the display panel according to some embodiments of the present disclosure is provided. The display panel comprises: a substrate; a first insulating layer on the substrate; a device structure layer on a side of the first insulating layer away from the substrate, wherein the device structure layer comprises a transparent capacitor and a transistor electrically connected to the transparent capacitor; a first planarization layer covering at least a portion of the device structure layer; a first electrode layer on a side of the first planarization layer away from the substrate, wherein the first electrode layer is electrically connected to the transparent capacitor, and the first electrode layer is a transparent electrode layer; a pixel defining layer on a side of the first planarization layer and the device structure layer away from the substrate, wherein the pixel defining layer has an opening exposing at least a portion of the first electrode layer, and an orthographic projection of the opening on the substrate at least partially overlaps with an orthographic projection of the transparent capacitor on the substrate; a functional layer located at least partially in the opening, wherein the functional layer is in contact with the first electrode layer, and the functional layer comprises a light-emitting layer; and a second electrode layer on a side of the functional layer away from the first electrode layer. In the display panel of the embodiment, the opening of the pixel defining layer is arranged above the transparent capacitor, and the light emitted by the light-emitting layer can be emitted from a bottom of the display panel. Compared with the structure in the related art in which the opening of the pixel defining layer is completely offset above the capacitor (for example, in the related art, an orthographic projection of the opening on the substrate does not overlap at all with an orthographic projection of the capacitor on the substrate), the structure of the display panel in the embodiments of the present disclosure can effectively increase the opening rate of the sub-pixels of the display panel, thereby helping to achieve a high PPI display effect.

In some embodiments, as shown in FIG. 1, the display panel further comprises a color filter layer 110 between the substrate 101 and the first insulating layer 120. The color filter layer 110 is on the substrate 101 and covered by the first insulating layer 120. The color filter layer 110 is a patterned color filter layer.

In some embodiments, an orthographic projection of the color filter layer 110 on the substrate 101 at least partially overlaps with the orthographic projection of the opening 172 on the substrate 101. For example, the orthographic projection of the opening 172 on the substrate 101 is inside the orthographic projection of the color filter layer 110 on the substrate 101.

In the above-described display panel, the color filter layer is formed on the substrate as a first layer structure, which can reduce a distance between the light-emitting layer and the substrate (for example, a glass substrate), thereby improving display brightness of the display panel. In addition, because the color filter layer is formed as the first layer structure, during the manufacturing process, it is possible to avoid a possible influence of the UV (ultraviolet) light irradiation used when the color filter layer is formed on a passivation layer in the related art on a threshold voltage of the transistor.

Of course, those skilled in the art can understand that, although FIG. 1 shows that the color filter layer is located on the substrate, those skilled in the art can understand that the position of the color filter layer in the embodiments of the present disclosure is not limited to this. The color film layer may be located in another position between the opening of the pixel defining layer and the substrate. For example, the color filter layer may be on a passivation layer (to be described later).

FIG. 2 is a schematic cross-sectional view showing a display panel according to another embodiment of the present disclosure. A structure in FIG. 2 that is similar to the structure in FIG. 1 will not be described in detail, and the difference between the structure in FIG. 2 and the structure in FIG. 1 will be described below.

In some embodiments, as shown in FIG. 2, the color filter layer 110 comprises a first color filter portion 111 and a second color filter portion 112 located in the same layer as the first color filter portion 111 and spaced apart from the first color filter portion 111. The orthographic projection of the opening 172 on the substrate 101 is inside an orthographic projection of the first color filter portion 111 on the substrate 101. The orthographic projection of the first color filter portion 111 on the substrate 101 is inside the orthographic projection of the fourth electrode layer 212 on the substrate 101. That is, the first color filter portion 111 is directly below the opening 172 of the pixel defining layer 170 and directly below the transparent capacitor 210.

In some embodiments, as shown in FIG. 2, an orthographic projection of the active layer 221 on the substrate 101 at least partially overlaps with an orthographic projection of the second color filter portion 112 on the substrate 101. For example, the orthographic projection of the active layer 221 on the substrate 101 is inside the orthographic projection of the second color filter portion 112 on the substrate 101. Here, the second color filter portion is used as a light-shielding layer of the transistor (for example, a driving transistor) to produce a light-shielding effect, which can reduce the influence of ambient light on a threshold voltage of the transistor, thereby improving the illumination stability of the transistor, and further improving the reliability of the backplane.

In addition, in the structure of the above-described display panel, the height of the transistor can be raised by arranging the color filter layer on the substrate, so that a vertical distance between the transistor and the light-emitting layer is reduced, thereby allowing the light emitted by the light-emitting layer to directly enter the environment after passing through the color filter below as much as possible, and reducing the influence of diffuse reflection inside the display panel on the threshold voltage of the transistor.

Furthermore, in the above-described display panel, since the color filter layer is arranged on the substrate, the opening of the pixel defining layer is used as a light-emitting area, and there is not a large segment difference below it, which can not only effectively improve the light-emitting efficiency, but also improve the degree of planarization, thereby improving the light-emitting uniformity of the display panel (especially the display panel manufactured by the inkjet printing process).

In some embodiments, as shown in FIG. 2, the display panel further comprises a passivation layer 410 between the pixel defining layer 170 and the device structure layer 20. A material of the passivation layer 410 is an insulating material (for example, silicon oxide, silicon nitride, or the like).

In some embodiments, as shown in FIG. 2, the first insulating layer 120 comprises a second planarization layer 121 on the substrate 101 and a buffer layer 122 on a side of the second planarization layer 121 away from the substrate 101. The second planarization layer 121 covers the color filter layer 110. For example, a material of the second planarization layer 121 comprises a planarization material such as resin or SOG. For example, a material of the buffer layer 122 comprises an insulating material such as silicon oxide, silicon nitride or silicon oxynitride.

So far, the display panel according to other embodiments of the present disclosure is provided. In the display panel, the second color filter portion is used as the light-shielding layer of the transistor, so that the influence of ambient light on the threshold voltage of the transistor can be reduced, thereby improving the illumination stability of the transistor. In addition, the structure of the display panel also reduces the influence of diffuse reflection of the light emitted by the light-emitting layer inside the display panel on the threshold voltage of the transistor.

Furthermore, in the related art, the color filter layer is formed on the passivation layer, which results in a large segment difference on the substrate, and requires a thick planarization layer to be planarized, so that there is a large distance between the light-emitting layer and the substrate, and the display brightness of the display panel is reduced. In the above-described display panel of the embodiments of the present disclosure, the color filter layer is formed on the substrate as the first layer structure, which can reduce the distance between the light-emitting layer and the substrate (for example, a glass substrate), thereby improving the display brightness of the display panel.

In some embodiments of the present disclosure, a display device is also provided. The display device comprises the display panel described above. For example, the display device may be any product or member with a display function, such as a display panel, a mobile phone, a tablet computer, a television, a displayer, a notebook computer, a digital photo frame, or a navigator.

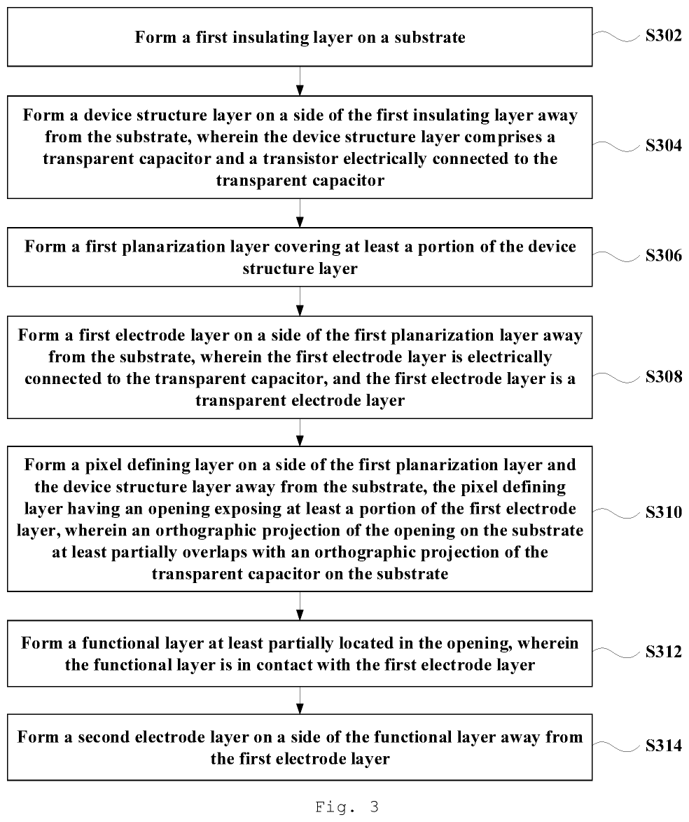

FIG. 3 is a flow chart showing a manufacturing method of a display panel according to an embodiment of the present disclosure. As shown in FIG. 3, the manufacturing method comprises steps S302 to S314.

In step S302, a first insulating layer is formed on a substrate.

In step S304, a device structure layer is formed on a side of the first insulating layer away from the substrate, wherein the device structure layer comprises a transparent capacitor and a transistor electrically connected to the transparent capacitor.

In some embodiments, the step S304 comprises: forming the transparent capacitor and the transistor.

In some embodiments, the forming of the transparent capacitor comprises: forming a third electrode layer on a side of the first insulating layer away from the substrate; forming a second insulating layer on the first insulating layer, the second insulating layer covering the third electrode layer; and forming a fourth electrode layer on a side of the second insulating layer away from the third electrode layer. The third electrode layer and the fourth electrode layer are transparent electrode layers. An area of the fourth electrode layer is less than an area of the third electrode layer.

In some embodiments, the forming of the transistor comprises: forming an active layer on a side of the second insulating layer away from the substrate, wherein the active layer and the fourth electrode layer are formed by a same patterning process; forming a gate insulating layer on a side of the active layer away from the second insulating layer; forming a gate electrode on a side of the gate insulating layer away from the active layer; and forming a fifth electrode layer electrically connected with the active layer. The gate electrode is electrically connected to the fourth electrode layer through a first connecting member. The fifth electrode layer is electrically connected to the third electrode layer.

In some embodiments, the forming of the device structure layer further comprises: forming an interlayer insulating layer covering the fourth electrode layer, the second insulating layer, the active layer and the gate electrode.

In step S306, a first planarization layer covering at least a portion of the device structure layer is formed.

In step S308, a first electrode layer is formed on a side of the first planarization layer away from the substrate, wherein the first electrode layer is electrically connected to the transparent capacitor, and the first electrode layer is a transparent electrode layer.

In step S310, a pixel defining layer is formed on a side of the first planarization layer and the device structure layer away from the substrate, the pixel defining layer having an opening exposing at least a portion of the first electrode layer, wherein an orthographic projection of the opening on the substrate at least partially overlaps with an orthographic projection of the transparent capacitor on the substrate. For example, the orthographic projection of the opening on the substrate is located inside an orthographic projection of the fourth electrode layer on the substrate.

In step S312, a functional layer at least partially located in the opening is formed, wherein the functional layer is in contact with the first electrode layer. The functional layer comprises a light-emitting layer.

In step S314, a second electrode layer is formed on a side of the functional layer away from the first electrode layer.

So far, a manufacturing method of a display panel according to some embodiments of the present disclosure is provided. In the display panel formed by the manufacturing method, the opening of the pixel defining layer is arranged above the transparent capacitor, so that the light emitted by the light-emitting layer can be emitted from a bottom of the display panel. Compared with the structure in the related art in which the opening of the pixel defining layer is completely offset above the capacitor, the structure of the display panel formed by the above-described method can effectively increase the opening rate of the sub-pixels of the display panel, thereby helping to achieve a high PPI display effect.

In some embodiments, the manufacturing method further comprises: forming a patterned color filter layer on the substrate before forming the first insulating layer. After the first insulating layer is formed, the color filter layer is covered by the first insulating layer. Since the color filter layer is arranged on the substrate, that is, the color filter layer is formed as the first layer structure during the manufacturing process, it is favorable for avoiding a possible influence of the UV light irradiation used when the color filter layer is formed on the passivation layer in the related art on a threshold voltage of the transistor.

FIGS. 4 to 8 are schematic cross-sectional views showing structures in several stages during a manufacturing process of a display panel according to an embodiment of the present disclosure. The manufacturing process of the display panel according to some embodiments of the present disclosure will be described in detail below in conjunction with FIGS. 4 to 8 and FIG. 2.

First, as shown in FIG. 4, a patterned color filter layer 110 is formed on the substrate 101. For example, the color filter layer may be first deposited and then patterned to form a first color filter portion 111 and a second color filter portion 112. For example, when the color filter layer is prepared, each color filter of B, G, or R (blue, green or red) can be deposited successively.

Next, as shown in FIG. 4, a first insulating layer 120 covering the color filter layer 110 is formed on the substrate 101. For example, the forming of the first insulating layer 120 comprises: forming a second planarization layer 121 on the substrate 101, the second planarization layer 121 covering the color filter layer 110; and forming a buffer layer 122 on a side of the second planarization layer 121 away from the substrate 101.

Next, as shown in FIG. 4, a third electrode layer 211 is formed on a side of the first insulating layer 120 away from the substrate 101. For example, a TCO layer and a metal layer are sequentially deposited on the substrate 101. Afterwards, a photoresist thereinafter is applied, and the TCO layer and the metal layer are patterned by a halftone mask to form a shielding pattern and the third electrode layer 211 (i.e., a lower electrode plate) of a transparent capacitor.

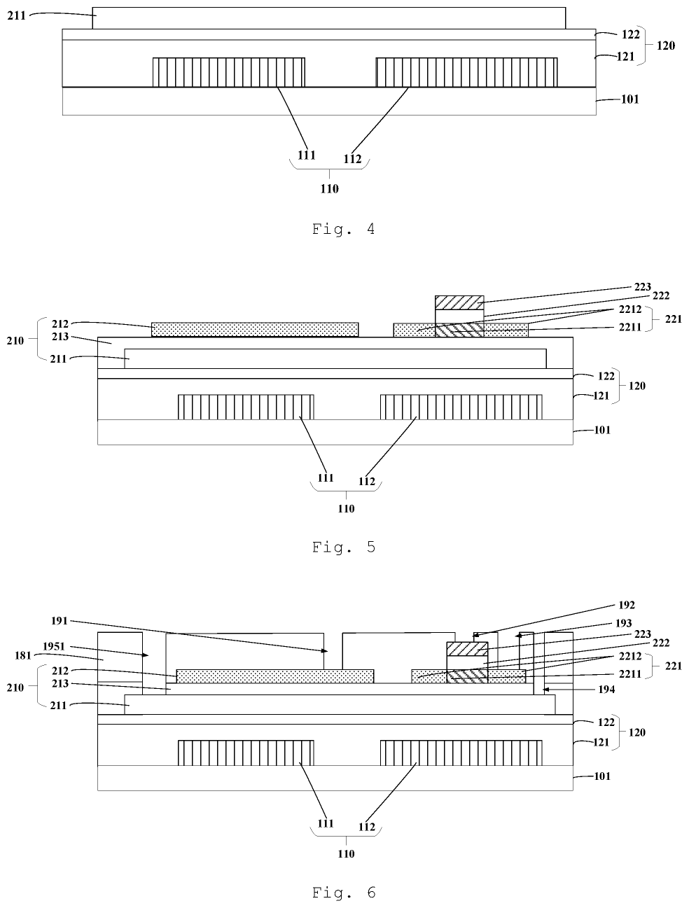

Next, as shown in FIG. 5, a second insulating layer 213 covering the third electrode layer 211 is formed on the first insulating layer 120 by a deposition process. A fourth electrode layer 212 and an active layer 221 are formed on a side of the second insulating layer 213 away from the third electrode layer 211 by processes such as deposition and wet etch patterning. The fourth electrode layer 212 serves as an upper electrode plate of the transparent capacitor. So far, a transparent capacitor 210 is formed.

Here, the active layer 221 and the fourth electrode layer 212 are formed by a same patterning process. The same patterning process means that a film layer for forming a specific pattern is formed using the same film forming process, and then a layer structure is formed by a single patterning process using the same mask.

Next, as shown in FIG. 5, a gate insulating layer 222 is formed on a side of the active layer 221 away from the second insulating layer 213, and a gate electrode 223 is formed on a side of the gate insulating layer 222 away from the active layer 221. For example, a gate insulating layer 222 can be deposited on the active layer 221, a gate electrode layer can be deposited on the gate insulating layer 222, and then a photoresist can be coated on the gate electrode layer. The gate insulating layer and the gate electrode layer are etched using a mask (for example, wet etching followed by dry etching), so that the gate insulating layer and the gate electrode layer are patterned to form the gate insulating layer 222 and the gate electrode 223 shown in FIG. 5. In addition, a LDD area 2212 of the active layer 221 and the fourth electrode layer 212 serving as the electrode plate of the transparent capacitor are conductively treated.

Next, as shown in FIG. 6, an interlayer insulating layer 181 covering the fourth electrode layer 212, the second insulating layer 213, the active layer 221, and the gate electrode 223 is formed. A first through hole 191, a second through hole 192, a third through hole 193, a fourth through hole 194 and a first portion 1951 of a fifth through hole are formed by a same etching process, the first through hole 191 passing through the interlayer insulating layer 181 and exposing a part of the fourth electrode layer 212, the second through hole 192 passing through the interlayer insulating layer 181 and exposing a part of the gate electrode 223, the third through hole 193 passing through the interlayer insulating layer 181 and exposing a part of the active layer 221, the fourth through hole 194 passing through the interlayer insulating layer 181 and the second insulating layer 213 and exposing a part of the third electrode layer 211, and the first portion 1951 of the fifth through hole passing through the interlayer insulating layer 181 and the second insulating layer 213 and exposing another part of the third electrode layer 211. Here, the first through hole 191, the second through hole 192, the third through hole 193, the fourth through hole 194 and the first portion 1951 of the fifth through hole are formed by a single photolithography process. That is, these through holes are formed by a single photolithography step, which can reduce the photoetching times, save the production cost, and improve the production yield.

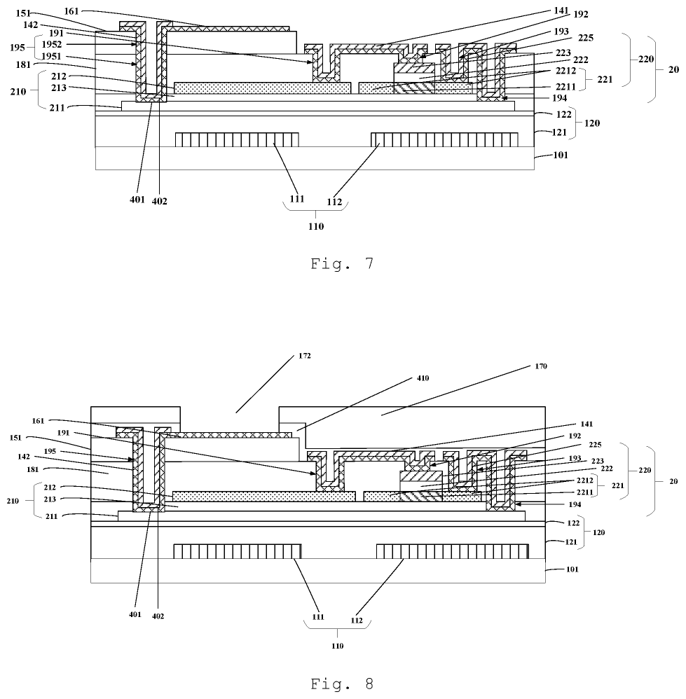

Next, as shown in FIG. 7, a first planarization layer 151 covering at least a portion of the device structure layer 20 is formed by deposition and patterning processes. After the first planarization layer 151 is formed, the first planarization layer 151 is etched to form a second portion 1952 of the fifth through hole passing through the first planarization layer 151, wherein the second portion 1952 is aligned with the first portion 1951. The second portion 1952 and the first portion 1951 form a fifth through hole 195.

Next, as shown in FIG. 7, a first electrode layer 161, a fifth electrode layer 225, a first connecting member 141 and a second connecting member 142 are formed by deposition and patterning processes, wherein the fifth electrode layer 225 is electrically connected to the active layer 221, the first connecting member 141 is connected to the gate electrode 223 and the fourth electrode layer 212, and the second connecting member 142 is connected to the first electrode layer 161 and the third electrode layer 211. For example, a transparent conductive layer 401 and a metal layer 402 can be sequentially deposited, and then the transparent conductive layer 401 and the metal layer 402 can be etched and patterned by a halftone mask to form the first electrode layer 161, the fifth electrode layer 225, the first connecting member 141 and the second connecting member 142.

Next, as shown in FIG. 8, a passivation layer 410 covering the first planarization layer 151 and the device structure layer 20 is formed by a deposition process, and a pixel defining layer 170 is formed on the passivation layer 410 by a deposition process. After the pixel defining layer 170 covering the passivation layer 410 is formed, an opening 172 passing through the pixel defining layer 170 and the passivation layer 410 is formed by a patterning process.

Next, as shown in FIG. 2, a functional layer 182 at least partially located in the opening 172 is formed by a deposition process. The functional layer 182 comprises a light-emitting layer. For example, the deposition process for the light-emitting layer may be a process such as evaporation or printing. Then, a second electrode layer 162 is formed on a side of the functional layer 182 away from the first electrode layer 161 by a deposition process.

So far, a manufacturing method of a display panel according to the embodiments of the present disclosure is provided. The structure of the display panel formed by the above-described method can effectively increase the opening rate of the sub-pixels of the display panel, thereby helping to achieve a high PPI display effect. During the manufacturing process, the color filter layer is formed as the first layer structure, so it is favorable for avoiding a possible influence of the UV light irradiation used when the color filter layer is formed on the passivation layer in the related art on a threshold voltage of the transistor. In addition, the above-described manufacturing method can reduce the photoetching times, save the production cost, and improve the production yield.

Hereto, various embodiments of the present disclosure have been described in detail. Some details well known in the art are not described in order to avoid obscuring the concept of the present disclosure. According to the above description, those skilled in the art would fully understand how to implement the technical solutions disclosed here.

Although some specific embodiments of the present disclosure have been described in detail by way of examples, those skilled in the art should understand that the above examples are only for the purpose of illustration but not for limiting the scope of the present disclosure. It should be understood by those skilled in the art that modifications to the above embodiments or equivalently substitution of part of the technical features may be made without departing from the scope and spirit of the present disclosure. The scope of the present disclosure is defined by the appended claims.

1. A display panel, comprising:
a substrate;
a first insulating layer on the substrate;
a device structure layer on a side of the first insulating layer away from the substrate, wherein the device structure layer comprises a transparent capacitor and a transistor electrically connected to the transparent capacitor;
a first planarization layer covering at least a portion of the device structure layer;
a first electrode layer on a side of the first planarization layer away from the substrate, wherein the first electrode layer is electrically connected to the transparent capacitor, and the first electrode layer is a transparent electrode layer;
a pixel defining layer on a side of the first planarization layer and the device structure layer away from the substrate, the pixel defining layer having an opening exposing at least a portion of the first electrode layer, wherein an orthographic projection of the opening on the substrate at least partially overlaps with an orthographic projection of the transparent capacitor on the substrate;
a functional layer at least partially located in the opening, wherein the functional layer is in contact with the first electrode layer, and the functional layer comprises a light-emitting layer; and
a second electrode layer on a side of the functional layer away from the first electrode layer.

2. The display panel according to claim 1, further comprising:
a color filter layer between the substrate and the first insulating layer.

3. The display panel according to claim 2, wherein an orthographic projection of the color filter layer on the substrate at least partially overlaps with the orthographic projection of the opening on the substrate.

4. The display panel according to claim 1, wherein the orthographic projection of the opening on the substrate is inside the orthographic projection of the transparent capacitor on the substrate.

5. The display panel according to claim 2, wherein the transparent capacitor comprises a third electrode layer on a side of the first insulating layer away from the substrate, a second insulating layer on the first insulating layer and covering the third electrode layer, and a fourth electrode layer on a side of the second insulating layer away from the third electrode layer, wherein the third electrode layer and the fourth electrode layer are transparent electrode layers, an area of the fourth electrode layer is less than an area of the third electrode layer, and the orthographic projection of the opening on the substrate is inside an orthographic projection of the fourth electrode layer on the substrate.

6. The display panel according to claim 5, wherein the color filter layer comprises a first color filter portion and a second color filter portion located in a same layer as the first color filter portion and spaced apart from the first color filter portion, wherein the orthographic projection of the opening on the substrate is inside an orthographic projection of the first color filter portion on the substrate, and the orthographic projection of the first color filter portion on the substrate is inside the orthographic projection of the fourth electrode layer on the substrate.

7. The display panel according to claim 6, wherein the transistor comprises:
an active layer on a side of the second insulating layer away from the substrate;
a gate insulating layer on a side of the active layer away from the second insulating layer;
a gate electrode on a side of the gate insulating layer away from the active layer, wherein the gate electrode is electrically connected to the fourth electrode layer through a first connecting member; and
a fifth electrode layer electrically connected to the active layer, wherein the fifth electrode layer is electrically connected to the third electrode layer.

8. The display panel according to claim 7, wherein the device structure layer further comprises:
an interlayer insulating layer covering the fourth electrode layer, the second insulating layer, the active layer and the gate electrode.

9. The display panel according to claim 8, wherein:
the first connecting member is connected to the fourth electrode layer through a first through hole passing through the interlayer insulating layer and exposing a part of the fourth electrode layer, and the first connecting member is connected to the gate electrode through a second through hole passing through the interlayer insulating layer and exposing a part of the gate electrode;
the fifth electrode layer is connected to the active layer through a third through hole passing through the interlayer insulating layer and exposing a part of the active layer, and the fifth electrode layer is connected to the third electrode layer through a fourth through hole passing through the interlayer insulating layer and the second insulating layer and exposing a part of the third electrode layer; and
the first electrode layer is electrically connected to the third electrode layer through a second connecting member, wherein the second connecting member is connected to the third electrode layer through a fifth through hole passing through the first planarization layer, the interlayer insulating layer and the second insulating layer and exposing another part of the third electrode layer.

10. The display panel according to claim 7, wherein an orthographic projection of the active layer on the substrate is inside an orthographic projection of the second color filter portion on the substrate.

11. The display panel according to claim 9, wherein the first connecting member, the fifth electrode layer and the second connecting member each comprise: a transparent conductive layer and a metal layer on a side of the transparent conductive layer away from the substrate.

12. The display panel according to claim 1, further comprising:
a passivation layer between the pixel defining layer and the device structure layer.

13. The display panel according to claim 1, wherein the first insulating layer comprises:
a second planarization layer on the substrate; and
a buffer layer on a side of the second planarization layer away from the substrate.

14. A display device, comprising: the display panel according to claim 1.

15. A manufacturing method of a display panel, comprising:
forming a first insulating layer on a substrate;
forming a device structure layer on a side of the first insulating layer away from the substrate, wherein the device structure layer comprises a transparent capacitor and a transistor electrically connected to the transparent capacitor;
forming a first planarization layer covering at least a portion of the device structure layer;
forming a first electrode layer on a side of the first planarization layer away from the substrate, wherein the first electrode layer is electrically connected to the transparent capacitor, and the first electrode layer is a transparent electrode layer;
forming a pixel defining layer on a side of the first planarization layer and the device structure layer away from the substrate, the pixel defining layer having an opening exposing at least a portion of the first electrode layer, wherein an orthographic projection of the opening on the substrate at least partially overlaps with an orthographic projection of the transparent capacitor on the substrate;
forming a functional layer at least partially located in the opening, wherein the functional layer is in contact with the first electrode layer, and the functional layer comprises a light-emitting layer; and
forming a second electrode layer on a side of the functional layer away from the first electrode layer.

16. The manufacturing method according to claim 15, further comprising:
forming a patterned color filter layer on the substrate before forming the first insulating layer, wherein the color filter layer is covered by the first insulating layer.

17. The manufacturing method according to claim 15, wherein the forming of the device structure layer comprises: forming the transparent capacitor and the transistor;
wherein the forming of the transparent capacitor comprises:
forming a third electrode layer on a side of the first insulating layer away from the substrate;
forming a second insulating layer on the first insulating layer, the second insulating layer covering the third electrode layer; and
forming a fourth electrode layer on a side of the second insulating layer away from the third electrode layer;
wherein the third electrode layer and the fourth electrode layer are transparent electrode layers, an area of the fourth electrode layer is less than an area of the third electrode layer, and the orthographic projection of the opening on the substrate is inside an orthographic projection of the fourth electrode layer on the substrate.

18. The manufacturing method according to claim 17, wherein the forming of the transistor comprises:
forming an active layer on a side of the second insulating layer away from the substrate, wherein the active layer and the fourth electrode layer are formed by a same patterning process;
forming a gate insulating layer on a side of the active layer away from the second insulating layer;
forming a gate electrode on a side of the gate insulating layer away from the active layer, wherein the gate electrode is electrically connected to the fourth electrode layer through a first connecting member; and
forming a fifth electrode layer electrically connected to the active layer, wherein the fifth electrode layer is electrically connected to the third electrode layer.

19. The manufacturing method according to claim 18, wherein:
the forming of the device structure layer further comprises: forming an interlayer insulating layer covering the fourth electrode layer, the second insulating layer, the active layer and the gate electrode; and
the manufacturing method further comprises:
forming a first through hole, a second through hole, a third through hole, a fourth through hole and a first portion of a fifth through hole by a same etching process, the first through hole passing through the interlayer insulating layer and exposing a part of the fourth electrode layer, the second through hole passing through the interlayer insulating layer and exposing a part of the gate electrode, the third through hole passing through the interlayer insulating layer and exposing a part of the active layer, the fourth through hole passing through the interlayer insulating layer and the second insulating layer and exposing a part of the third electrode layer, and the first portion of the fifth through hole passing through the interlayer insulating layer and the second insulating layer and exposing another part of the third electrode layer; and
etching the first planarization layer to form a second portion of the fifth through hole passing through the first planarization layer after forming the first planarization layer, wherein the second portion is aligned with the first portion;
wherein the first connecting member, the fifth electrode layer, the first electrode layer and a second connecting member are formed by deposition and patterning processes after forming the first through hole, the second through hole, the third through hole, the fourth through hole and the fifth through hole, wherein the second connecting member is connected to the first electrode layer and the third electrode layer.

20. The manufacturing method according to claim 19, further comprising:
forming a passivation layer covering the first planarization layer and the device structure layer before forming the pixel defining layer; and
forming the opening passing through the pixel defining layer and the passivation layer by a patterning process after forming the pixel defining layer covering the passivation layer.
